(19) United States
(12) Patent Application Publication
(10) Pub. No.: US 2026/0032844 A1
(43) Pub. Date: Jan. 29, 2026

(54) SUPPORT DEVICE FOR MOUNTING ELECTRONIC EQUIPMENT

(71) Applicant: LITE-ON TECHNOLOGY CORPORATION, Taipei (TW)

(72) Inventors: Cheng-Hsuen CHIEN, Taipei (TW); Wei-Ming Shieh, Taipei (TW); Hsiao-Ming Chen, Taipei (TW)

(21) Appl. No.: 19/006,335

(22) Filed: Dec. 31, 2024

Related U.S. Application Data
(60) Provisional application No. 63/674,326, filed on Jul. 23, 2024.

(30) Foreign Application Priority Data
Oct. 30, 2024 (CN) 202411529510.8

(51) Int. Cl. H05K 7/14; H05K 9/00

(52) U.S. Cl. CPC H05K 7/1425; H05K 7/1418; H05K 9/0037

(57) ABSTRACT

A support device for mounting electronic equipment is provided. The support device includes a panel assembly including a hole, an electromagnetic shielding assembly, a housing assembly disposed between the panel assembly and the electromagnetic shielding assembly and including a housing bulge part, a bracket assembly and an accommodation assembly on the bracket assembly and for accommodating the electronic equipment. The housing bulge part is disposed in the hole of the panel assembly. The housing bulge part is exposed by the hole of the panel assembly. The electromagnetic shielding assembly is disposed between the housing assembly and the bracket assembly.

This application claims the benefit of U.S. provisional application Ser. No. 63/674,326, filed Jul. 23, 2024, and People's Republic of China application Serial No. 202411529510.8, filed Oct. 30, 2024, the subject matters of which are incorporated herein by reference.

### BACKGROUND

### Technical Field

The present disclosure relates to a support device, and more particularly to a support device for mounting electronic equipment.

### Description of the Related Art

Cage can be used to accommodate one or more electronic equipment. In order to facilitate check, maintenance or replacement of electronic equipment in the cage, the electronic equipment is usually mounted on a support device, so that the electronic equipment can be installed in the cage through the support device. The conventional support device is composed of a large number of elements, resulting in high manufacturing cost and making it unsuitable for automated assembly, which causes a lot of inconvenience and does not meet the needs.

### SUMMARY

The present disclosure provides a support device for mounting electronic equipment, which is suitable for automated assembly, can be manufactured with low cost and can improve the aforementioned problems in the existing technology.

According to some embodiments, a support device for mounting electronic equipment is provided. The support device includes a panel assembly including a hole, an electromagnetic shielding assembly, a housing assembly disposed between the panel assembly and the electromagnetic shielding assembly and including a housing bulge part, a bracket assembly, and an accommodation assembly on the bracket assembly and for accommodating the electronic equipment. The housing bulge part is disposed in the hole of the panel assembly. The housing bulge part is exposed by the hole of the panel assembly. The electromagnetic shielding assembly is disposed between the housing assembly and the bracket assembly.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a support device according to the first embodiment of the present disclosure.

FIG. 2 illustrates a schematic view of the support device according to the first embodiment of the present disclosure.

FIG. 3A illustrates a schematic exploded view of some elements of the support device according to the first embodiment of the present disclosure.

FIG. 3B illustrates a schematic exploded view of some elements of the support device according to the first embodiment of the present disclosure.

FIG. 4A illustrates a schematic view of the assembly of some elements of the support device according to the first embodiment of the present disclosure.

FIG. 4B illustrates a schematic view of the assembly of some elements of the support device according to the first embodiment of the present disclosure.

FIG. 5 illustrates a partial schematic view of an accommodation assembly according to the first embodiment of the present disclosure.

FIG. 6 illustrates a partial perspective view of the support device according to the first embodiment of the present disclosure.

FIG. 7 illustrates a schematic view of a support device according to the second embodiment of the present disclosure.

FIG. 8 illustrates a schematic view of the support device according to the second embodiment of the present disclosure.

FIG. 9A illustrates a schematic exploded view of some elements of the support device according to the second embodiment of the present disclosure.

FIG. 9B illustrates a schematic exploded view of some elements of the support device according to the second embodiment of the present disclosure.

FIG. 10A illustrates a schematic view of the assembly of some elements of the support device according to the second embodiment of the present disclosure.

FIG. 10B illustrates a schematic view of the assembly of some elements of the support device according to the second embodiment of the present disclosure.

FIG. 11 illustrates a partial perspective view of the support device according to the second embodiment of the present disclosure.

### DETAILED DESCRIPTION

Various embodiments will be described more fully hereinafter with reference to accompanying drawings. For clarity, the elements may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

The present disclosure provides embodiments of support devices. The support device can be used to mount electronic equipment, such as a server or a data storage device. The data storage device can be a hard disk drive (HDD) or a solid-state drive (SSD). The electronic equipment can be mounted (e.g. fastened) on the support device, the support device is detachably installed in the cage, and thus the electronic equipment together with the support device can be detachably installed in the cage. In some embodiments, the support device according to the present disclosure can be used to mount E3.S solid-state drives based on EDSFF.

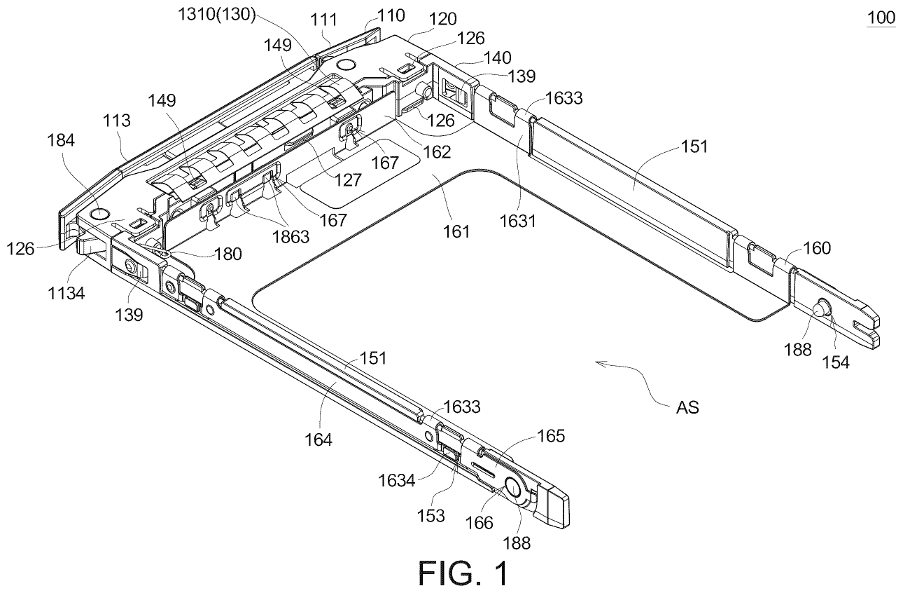

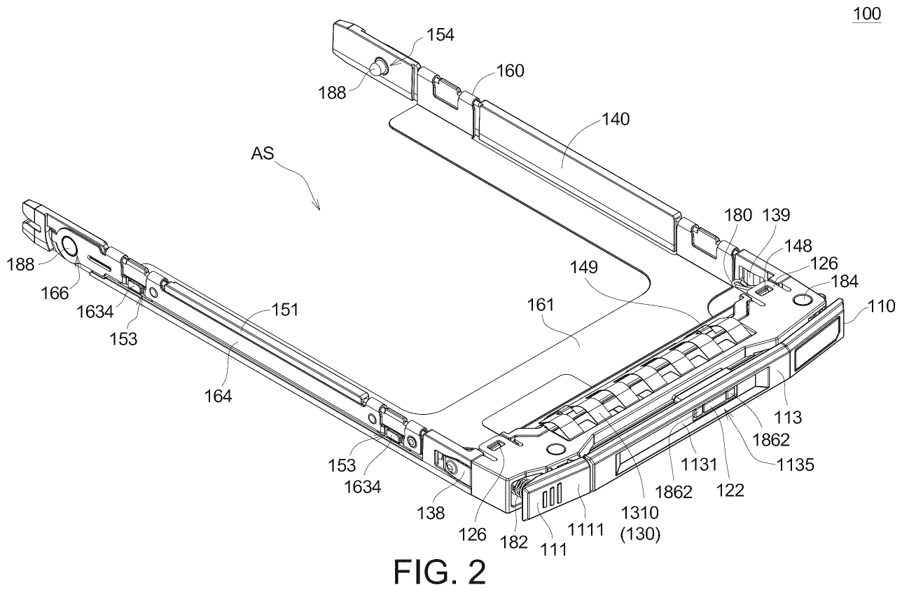

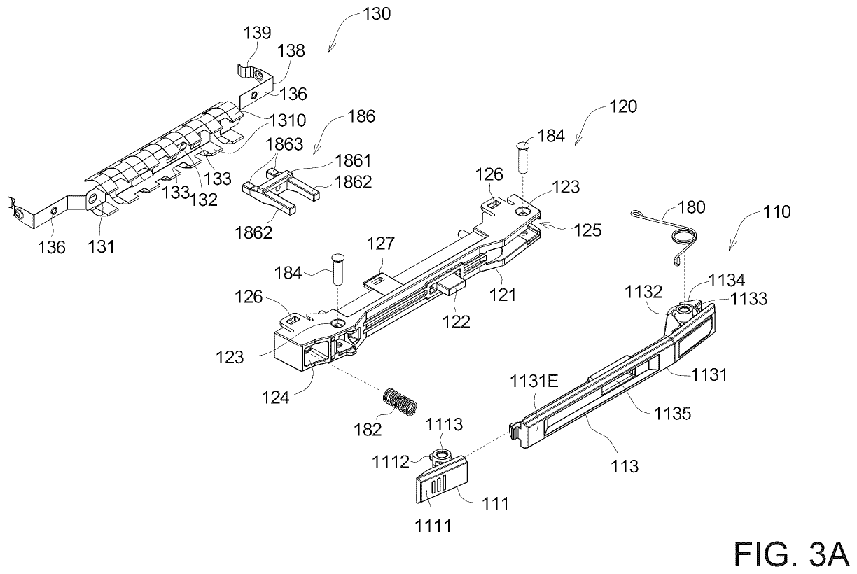

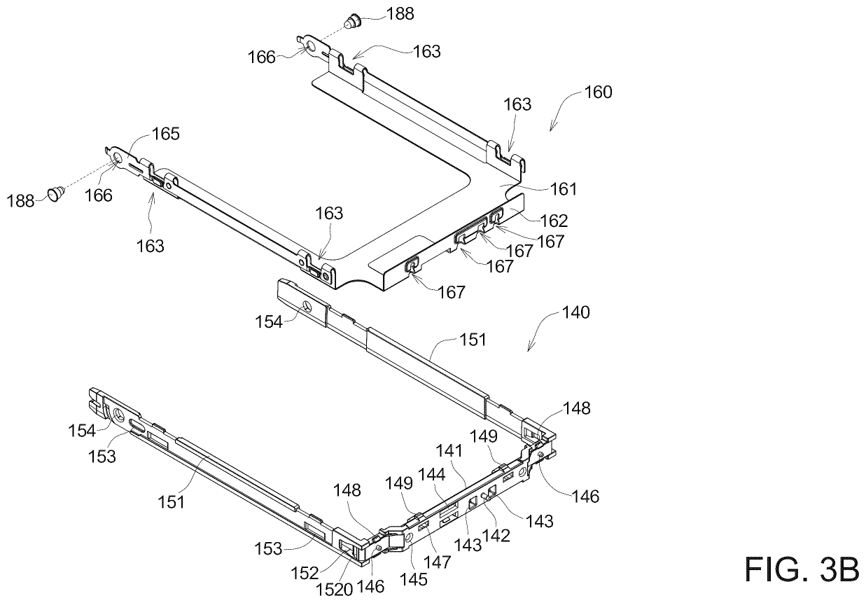

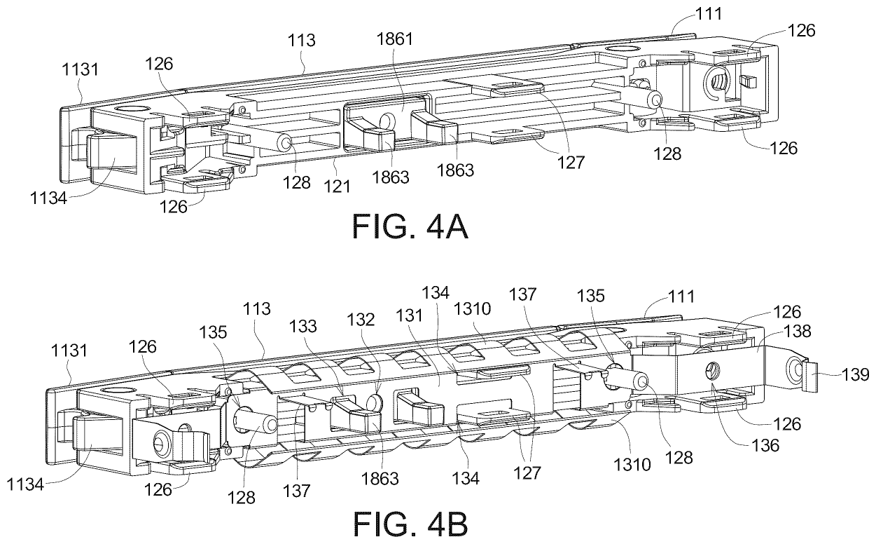

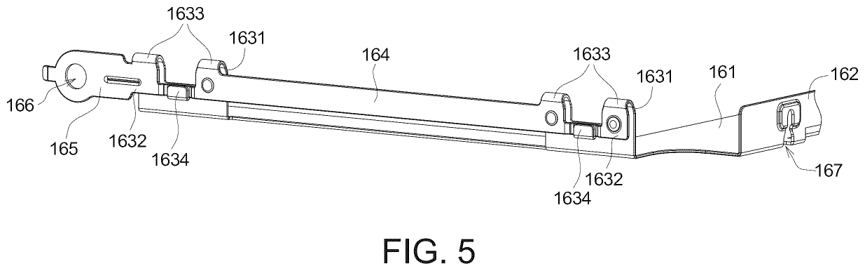

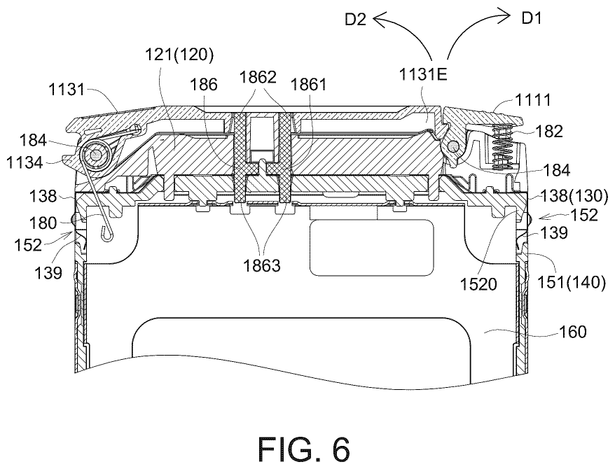

Referring to FIG. 1 to FIG. 6, FIG. 1 illustrates a schematic view of a support device 100 according to the first embodiment of the present disclosure, FIG. 2 illustrates a schematic view of the support device 100 according to the first embodiment of the present disclosure from different viewing angles, FIG. 3A illustrates a schematic exploded view of some elements of the support device 100 according to the first embodiment of the present disclosure, FIG. 3B illustrates a schematic exploded view of some elements of the support device 100 according to the first embodiment of the present disclosure, FIG. 4A illustrates a schematic view of the assembly of some elements of the support device 100 according to the first embodiment of the present disclosure, FIG. 4B illustrates a schematic view of the assembly of some elements of the support device 100 according to the first embodiment of the present disclosure, FIG. 5 illustrates a partial schematic view of an accommodation assembly 160 according to the first embodiment of the present disclosure, and FIG. 6 illustrates a partial perspective view of the support device 100 according to the first embodiment of the present disclosure, viewed from top of the support device 100.

The support device 100 includes a panel assembly 110, an electromagnetic shielding assembly 130, a housing assembly 120, a bracket assembly 140 and an accommodation assembly 160. The housing assembly 120 is disposed between the panel assembly 110 and the electromagnetic shielding assembly 130. The electromagnetic shielding assembly 130 is disposed between the housing assembly 120 and the bracket assembly 140. The accommodation assembly 160 is disposed on the bracket assembly 140 and is used to accommodate or mount electronic equipment. As shown in FIG. 3A, the panel assembly 110 includes a hole 1135. As shown in FIG. 3A, the housing assembly 120 includes a housing bulge part 122. As shown in FIG. 2, the housing bulge part 122 of the housing assembly 120 is disposed in the hole 1135 of the panel assembly 110, and the housing bulge part 122 is exposed by the hole 1135 of the panel assembly 110.

The panel assembly 110 includes a button 111 and a handle 113. The button 111 abuts the handle movable end 1131E of the handle 113. The button 111 includes a button body 1111, a button bulge part 1112 and a button through hole 1113. The button bulge part 1112 is disposed on a rear surface of the button body 1111 and protrudes from the rear surface of the button body 1111. The rear surface of the button body 1111 faces the housing assembly 120. The button through hole 1113 extends along a direction parallel to the rear surface of the button body 1111 (or can be understood as a longitudinal direction) and penetrates the button bulge part 1112. The handle 113 includes a handle body 1131, a handle bulge part 1132, a handle through hole 1133, a handle hook part 1134 and a hole 1135. The handle bulge part 1132 is disposed on a rear surface of the handle body 1131 and protrudes from the rear surface of the handle body 1131. The rear surface of the handle body 1131 faces the housing assembly 120. The handle through hole 1133 extends along a direction parallel to the rear surface of the handle body 1131 (or can be understood as a longitudinal direction) and penetrates the handle bulge part 1132. The handle hook part 1134 is disposed on the handle bulge part 1132 and extends toward the outside of the support device 100. The hole 1135 is disposed in the handle body 1131. The hole 1135 extends from a rear surface of the handle body 1131 to a front surface of the handle body 1131 opposite to the rear surface of the handle body 1131. When the support device 100 is installed in a cage, the handle hook part 1134 can be engaged with a corresponding attachment structure of the cage to increase the connection stability between the support device 100 and the cage. When the support device 100 is installed in a cage, the front surface of the handle body 1131 can face the user. The panel assembly 110 may be made of a polymer material, such as polycarbonate (PC), acrylonitrile butadiene styrene (ABS) or a combination thereof.

The housing assembly 120 includes a housing body 121, a housing bulge part 122, a housing through hole 123, a recess 124, a channel 125, a housing snap portion 126, an extended piece 127 and a housing limit portion 128. In the present embodiment, the drawings show that the housing assembly 120 includes two housing through holes 123, four housing snap portions 126, two extended pieces 127 and two housing limit portions 128; however, the numbers of the housing through hole 123, the housing snap portion 126, the extended piece 127 and the housing limit portion 128 are not limited to the numbers shown in the drawings. The housing bulge part 122 protrudes from a front surface of the housing body 121 and extends toward the panel assembly 110. The front surface of the housing body 121 faces a rear surface of the panel assembly 110. The position of the housing bulge part 122 can correspond to the position of the hole 1135 of the panel assembly 110. The housing through holes 123 may be disposed at opposite ends of the housing body 121. The housing through holes 123 may extend along the longitudinal direction and penetrate the housing body 121. The recess 124 and the channel 125 can be disposed at opposite ends of the housing body 121. The recess 124 has an opening toward the button 111 of the panel assembly 110. The channel 125 has an opening toward the handle 113 of the panel assembly 110 and the outside of the support device 100. The channel 125 is used to accommodate at least a portion of the handle bulge part 1132 and at least a portion of the handle hook part 1134 (as shown in FIG. 1 and FIG. 6). The channel 125 can communicate with one of the housing through holes 123.

The housing snap portion 126 protrudes from a rear surface of the housing body 121 and extends toward the electromagnetic shielding assembly 130. The rear surface of the housing body 121 is opposite to the front surface of the housing body 121. The rear surface of the housing body 121 faces the electromagnetic shielding assembly 130. The housing snap portions 126 can be disposed on the housing body 121 and separated from each other. In the present embodiment, two housing snap portions 126 are disposed close to an upper surface of the housing body 121, and two housing snap portions 126 are disposed close to a lower surface of the housing body 121; the present disclosure is not limited thereto. The extended piece 127 protrudes from the rear surface of the housing body 121 and extends toward the electromagnetic shielding assembly 130. The extended pieces 127 can be disposed on the housing body 121 and separated from each other. In the present embodiment, one extended piece 127 is disposed close to the upper surface of the housing body 121, and another extended piece 127 are disposed close to the lower surface of the housing body 121; the present disclosure is not limited thereto. The extended pieces 127 can be disposed between the housing snap portions 126. The extended pieces 127 can be disposed between the housing limit portions 128. The housing limit portions 128 can be disposed at opposite ends of the housing body 121. The housing limit portion 128 can be disposed between the extended piece 127 and the housing snap portion 126. The housing limit portion 128 protrudes from the rear surface of the housing body 121 and extends toward the electromagnetic shielding assembly 130. The housing limit portions 128 can be separated from each other. As shown in FIG. 2, the panel assembly 110 can cover the front surface of the housing body 121. The housing assembly 120 may be made of a polymer material, such as polycarbonate (PC), acrylonitrile butadiene styrene (ABS) or a combination thereof.

The electromagnetic shielding assembly 130 includes a body 131, a finger portion 1310, a positioning hole 132, a first through hole 133, a second through hole 134, a third through hole 135, a fourth through hole 136, a conductive piece 137, an extended portion 138 and an elastic structure 139. In the present embodiment, the drawings show that the electromagnetic shielding assembly 130 includes two finger portions 1310, two first through holes 133, two second through holes 134, two third through holes 135, two fourth through holes 136, two conductive pieces 137, two extended portions 138 and two elastic structures 139; however, the numbers of the finger portion 1310, the first through hole 133, the second through hole 134, the third through hole 135, the fourth through hole 136, the conductive piece 137, the extended portion 138 and the elastic structure 139 are not limited to the numbers shown in the drawings. The body 131 is disposed or connected between two finger portions 1310. Two finger portions 1310 are disposed on opposite sides of the body 131. The finger portions 1310 can extend toward the housing assembly 120. The finger portions 1310 can be separated from each other. The body 131 can cover the rear surface of the housing body 121 of the housing assembly 120. One finger portion 1310 of the two finger portions 1310 can cover a first surface or an upper surface of the housing body 121 of the housing assembly 120, and the other one of the two finger portions 1310 can cover a second surface or a lower surface of the housing body 121 of the housing assembly 120. As shown in FIG. 4B, the positioning hole 132 can extend from a front surface of the body 131 to a rear surface of the body 131 opposite the front surface. The front surface of the body 131 faces the rear surface of the housing body 121 of the housing assembly 120. The rear surface of the body 131 faces the bracket assembly 140. As shown in FIG. 4B, two first through holes 133 can be disposed on opposite sides of the positioning hole 132. The first through holes 133 can extend from the front surface of the body 131 to the rear surface of the body 131. As shown in FIG. 4B, the second through hole 134 can extend from the front surface of the body 131 to the rear surface of the body 131. Two second through holes 134 may be disposed along the longitudinal direction. The position of the second through hole 134 can correspond to the position of the extended piece 127 of the housing assembly 120. As shown in FIG. 4B, two third through holes 135 can be disposed on opposite sides of the positioning hole 132. The third through holes 135 can extend from the front surface of the body 131 to the rear surface of the body 131. The position of the third through hole 135 can correspond to the position of the housing limit portion 128 of the housing assembly 120. The conductive piece 137 can protrude from the rear surface of the body 131 and extend toward the bracket assembly 140. The conductive pieces 137 can be separated from each other. Two conductive pieces 137 can be disposed on opposite sides of the positioning hole 132. The conductive pieces 137 can be disposed between the third through holes 135. The positioning hole 132, the first through holes 133 and the second through holes 134 can be disposed between two conductive pieces 137. The conductive piece 137 can be formed by bending the material of the body 131.

Two extended portions 138 can be disposed at opposite ends of the body 131. The extended portion 138 can extend from the end of the body 131 toward the outside of the support device 100. The extended portion 138 may have a bending structure. The extended portion 138 may be bent toward the bracket assembly 140. The elastic structure 139 is disposed at the end of the extended portion 138. The extended portion 138 can be connected between the elastic structure 139 and the body 131. The elastic structure 139 may have a curved structure. The elastic structure 139 may include a concave part that is recessed toward the interior of the support device 100 (i.e. the opening of the concave part is toward the outside of the support device 100). As shown in FIG. 4B, two fourth through holes 136 can be disposed on opposite sides of the positioning hole 132. The fourth through hole 136 can penetrate the extended portion 138. The third through hole 135 can be disposed between the fourth hole 136 and the conductive piece 137. The housing assembly 120 can cover the front surface of the body 131 of the electromagnetic shielding assembly 130. The electromagnetic shielding assembly 130 may be made of a conductive material, such as SUS301 stainless steel. In an embodiment, the extended portion 138 and/or the elastic structure 139 can contact the cage for electrostatic discharge, which can improve the electrostatic protection capability of the support device 100.

The bracket assembly 140 includes a bracket body 141, a first column 142, a first bracket through hole 143, a second bracket through hole 144, a third bracket through hole 145, a second column 146, a fourth bracket through hole 147, a snap portion 148, an extension structure 149, a side arm 151, a receiving hole 152, a concavity 153 and a fastening hole 154. In the present embodiment, the drawings show that the bracket assembly 140 includes one first column 142, two first bracket through holes 143, two second bracket through holes 144, two third bracket through holes 145, two second columns 146, two fourth bracket through holes 147, four snap portions 148, four extension structures 149, two side arms 151, two receiving holes 152, four concavities 153 and two fastening holes 154; however, the numbers of the first column 142, the first bracket through hole 143, the second bracket through hole 144, the third bracket through hole 145, the second column 146, the fourth bracket through hole 147, the snap portion 148, the extension structure 149, the side arm 151, the receiving hole 152, the concavity 153 and the fastening hole 154 are not limited to the numbers shown in the drawings. The bracket body 141 is disposed or connected between two side arms 151. The side arm 151 can extend in a direction away from the electromagnetic shielding assembly 130.

As shown in FIG. 3B, the first column 142 is disposed on a front surface of the bracket body 141. The first column 142 protrudes from the front surface of the bracket body 141. The front surface of the bracket body 141 faces the rear surface of the body 131 of the electromagnetic shielding assembly 130. The position of the first column 142 can correspond to the position of the positioning hole 132 of the electromagnetic shielding assembly 130. Two first bracket through holes 143 can be disposed on opposite sides of the first column 142. The first bracket through hole 143 can extend from the front surface of the bracket body 141 to a rear surface of the bracket body 141 opposite the front surface of the bracket body 141. The position of the first bracket through holes 143 can correspond to the position of the first through holes 133 of the electromagnetic shielding assembly 130. Two second bracket through holes 144 can extend from the front surface of the bracket body 141 to the rear surface of the bracket body 141. Two second bracket through holes 144 can be disposed along the longitudinal direction. The position of the second bracket through holes 144 can correspond to the position of the second through holes 134 of the electromagnetic shielding assembly 130. Two third bracket through holes 145 can be disposed on opposite sides of the first column 142. The third bracket through holes 145 can extend from the front surface of the bracket body 141 to the rear surface of the bracket body 141. The position of the third bracket through holes 145 can correspond to the position of the third through holes 135 of the electromagnetic shielding assembly 130. The second columns 146 are disposed on the front surface of the bracket body 141. The second columns 146 protrude from the front surface of the bracket body 141. Two second columns 146 can be disposed on opposite sides of the bracket body 141. Two second columns 146 can be disposed on opposite sides of the first column 142. The position of the second columns 146 can correspond to the position of the fourth through holes 136 of the electromagnetic shielding assembly 130. Two fourth bracket through holes 147 can be disposed on opposite sides of the first column 142. The fourth bracket through holes 147 can extend from the front surface of the bracket body 141 to the rear surface of the bracket body 141. The position of the fourth bracket through holes 147 can correspond to the position of the conductive pieces 137 of the electromagnetic shielding assembly 130. The first column 142, the first bracket through holes 143 and the second bracket through holes 144 can be disposed between two fourth bracket through holes 147. The third bracket through hole 145 can be disposed between the second column 146 and the fourth bracket through hole 147. Two of four snap portions 148 are disposed separately on the first edge of the bracket body 141 and protrude from the first edge of the bracket body 141, and the other two of the four snap portions 148 are disposed separately on the second edge of the bracket body 141 and protrude from the second edge of the bracket body 141; the first edge is opposite to the second edge. The position of the snap portions 148 can correspond to the housing snap portions 126 of the housing assembly 120. Two of four extension structures 149 are disposed separately on the first edge of the bracket body 141 and protrude from the first edge of the bracket body 141, and the other two of the four extension structures 149 are disposed separately on the second edge of the bracket body 141 and protrude from the second edge of the bracket body 141. The extension structure 149 can be disposed between the snap portions 148.

The housing snap portion 126 of the housing assembly 120 is coupled to the snap portion 148 of the bracket assembly 140 so that the housing assembly 120 is fixed to the bracket assembly 140. The extended piece 127 of the housing assembly 120 passes through the second through hole 134 of the electromagnetic shielding assembly 130 and the second bracket through hole 144 of the bracket assembly 140. The housing limit portion 128 of the housing assembly 120 passes through the third through hole 135 of the electromagnetic shielding assembly 130 and the third bracket through hole 145 of the bracket assembly 140. The first column 142 of the bracket assembly 140 can pass through the positioning hole 132 of the electromagnetic shielding assembly 130. The second column 146 of the bracket assembly 140 can pass through the fourth through hole 136 of the electromagnetic shielding assembly 130. The conductive piece 137 of the electromagnetic shielding assembly 130 can pass through the fourth bracket through hole 147 of the bracket assembly 140. The extension structure 149 of the bracket assembly 140 can pass through the finger portion 1310 of the electromagnetic shielding assembly 130. The extension structures 149 of the bracket assembly 140 can be disposed in the gaps between the fingers of the finger portions 1310 of the electromagnetic shielding assembly 130. The extension structures 149 can cover a portion of the surface of the finger portion 1310. The movement of the finger portions 1310 can be limited by the extension structures 149.

The receiving holes 152, the concavities 153 and the fastening holes 154 are disposed on a side of the bracket assembly 140. The receiving holes 152, the concavities 153 and the fastening holes 154 are disposed on the side arms 151. The receiving holes 152 and the fastening holes 154 can penetrate the side arms 151. The opening of the concavity 153 faces the outside of the support device 100. The concavity 153 may be recessed from the outside toward the inside of the support device 100. The concavity 153 may be disposed between the receiving hole 152 and the fastening hole 154. The elastic structure 139 of the electromagnetic shielding assembly 130 can be disposed in the receiving hole 152 so that the electromagnetic shielding assembly 130 is coupled to the bracket assembly 140. As shown in FIG. 6, the receiving hole 152 can include a guide ramp 1520 for guiding the elastic structure 139 into the receiving hole 152. As shown in FIG. 6, when the electromagnetic shielding assembly 130 is coupled to the bracket assembly 140, the end of the elastic structure 139 is limited by the side arm 151 to fix the electromagnetic shielding assembly 130 to the bracket assembly 140. The assembly of the electromagnetic shielding assembly 130 and the bracket assembly 140 can be achieved through the guiding of the guide ramp 1520, which is conducive to automated assembly. The electromagnetic shielding assembly 130 can cover the front surface of the bracket body 141 of the bracket assembly 140. The bracket assembly 140 may be made of a polymer material, such as polycarbonate (PC), acrylonitrile butadiene styrene (ABS) or a combination thereof.

The accommodation assembly 160 includes a bottom plate 161, a front plate 162, a coupling structure 163, a connection arm 164, an end plate 165, a connection hole 166 and a penetrating hole 167. In the present embodiment, the drawings show that the accommodation assembly 160 includes four coupling structures 163, two connection arms 164, two end plates 165, two connection holes 166 and four penetrating holes 167; however, the numbers of the coupling structure 163, the connection arm 164, the end plate 165, the connection holes 166 and the penetrating holes 167 are not limited to the numbers shown in the drawings. The bottom plate 161 can be used to support the electronic equipment (e.g. data storage device). The front plate 162 is disposed on the first edge of the bottom plate 161. The front plate 162 can cover the rear surface of the bracket body 141. The penetrating holes 167 can be separated from each other on the front plate 162. The coupling structure 163 can be disposed on the second edge and the third edge of the bottom plate 161; the second edge is opposite to the third edge; the first edge is between the second edge and the third edge. In the present embodiment, the coupling structures 163 are approximately symmetrically arranged on the second edge and the third edge of the bottom plate 161, but the present disclosure is not limited thereto. The position and number of the coupling structure 163 can be adjusted based on needs. As shown in FIG. 5, the coupling structure 163 includes a back plate 1631, a cover piece 1632, a connection piece 1633 and a limit element 1634. The connection piece 1633 is connected between the back plate 1631 and the cover piece 1632. The connection piece 1633 protrudes from a surface of the back plate 1631 that is toward the outside of the support device 100. The cover piece 1632 can be parallel or substantially parallel to the back plate 1631. In the present embodiment, the back plate 1631 can be connected to two connection pieces 1633, each connection piece 1633 is connected to one cover piece 1632, the limit element 1634 is disposed or connected between two cover pieces 1632 which are separated from each other, but the present disclosure is not limited thereto. The cover piece 1632, the number of the connection piece 1633 and the limit element 1634 of the coupling structure 163 can be adjusted based on needs. The back plate 1631, the cover piece 1632, the connection piece 1633 and the limit element 1634 can define a holding space, and the side arm 151 of the bracket assembly 140 is disposed in the holding space. Specifically, when the accommodation assembly 160 is assembled to the bracket assembly 140, the back plate 1631 covers the inner surface of the side arm 151 of the bracket assembly 140, the cover piece 1632 covers the outer surface of the side arm 151 of the bracket assembly 140 and the limit element 1634 is disposed in the cavity 153 of the bracket assembly 140; the inner surface of the side arm 151 of the bracket assembly 140 is opposite to the outer surface of the side arm 151 of the bracket assembly 140; the outer surface of the side arm 151 of the bracket assembly 140 faces the outside of the support device 100. The back plate 1631, the cover piece 1632 and the connection piece 1633 cover the side arm 151 of the bracket assembly 140, and the limit element 1634 is disposed in the cavity 153 of the bracket assembly 140, so that the movement of the bracket assembly 140 relative to the accommodation assembly 160 can be limited and the bracket assembly 140 can be fixed to the accommodation assembly 160. The connection arm 164 can be disposed or connected between two coupling structures 163. The connection arm 164 can be connected to one cover piece 1632 of one coupling structure 163 and one cover piece 1632 of another one coupling structure 163. The connection arm 164 can cover the outer surface of the side arm 151 of the bracket assembly 140. The connection arm 164 improve the structural strength of the accommodation assembly 160 and the assembly stability of the bracket assembly 140 and the accommodation assembly 160. The end plate 165 can be disposed at the end of the accommodation assembly 160 and connected to the coupling structure 163. The coupling structure 163 and the connection arm 164 can be disposed between the front plate 162 and the end plate 165. The end plate 165 may extend in a direction away from the front plate 162. The connection hole 166 can penetrate the end plate 165. The position of the connection holes 166 can correspond to the fastening holes 154 of the bracket assembly 140.

The accommodation assembly 160 may include an accommodation space AS for accommodating electronic equipment (e.g. data storage device). The accommodation space AS can be defined by the bottom plate 161, the front plate 162, the coupling structures 163, the connection arms 164 and the end plates 165. The electronic equipment can be disposed in the accommodation space AS and coupled to the bracket assembly 140 and/or the accommodation assembly 160. The electronic equipment can contact the bracket assembly 140 and/or the accommodation assembly 160. In an embodiment, the electronic equipment can be fixed (or coupled) in the accommodation space AS of the accommodation assembly 160 without using fastening component such as screw. The accommodation assembly 160 can contact the cage for electrostatic discharge, which can improve the electrostatic protection capability of the support device 100. The conductive piece 137 of the electromagnetic shielding assembly 130 can contact the front plate 162 of the accommodation assembly 160. The electromagnetic shielding assembly 130, the accommodation assembly 160 and the electronic equipment mounted on the support device 100 can form a conductive path for electrostatic discharge, grounding, etc., which can effectively increase the electromagnetic interference (EMI) protection.

The support device 100 may further include a first elastic element 180, a second elastic element 182, positioning pins 184, a connection element 186 and fasteners 188. The first elastic element 180 is disposed on one side of the handle bulge part 1132 of the handle 113. The first elastic element 180 is disposed above the handle bulge part 1132 of the handle 113. A portion of the first elastic element 180 may surround the handle through hole 1133. A portion of the first elastic element 180 may be in the channel 125 of the housing assembly 120, and another portion of the first elastic element 180 may protrude from the rear surface of the bracket body 141 and be disposed in the accommodation space AS (as shown in FIG. 1). For example, the first elastic element 180 is a torsion spring. At least a portion of the handle bulge part 1132 is disposed in the channel 125 of the housing assembly 120 so that the handle through hole 1133 overlaps one of the housing through holes 123 of the housing assembly 120. At least a portion of the button bulge part 1112 is disposed in the housing assembly 120 so that the button through hole 1113 overlaps another one of the housing through holes 123 of the housing assembly 120. One of the positioning pins 184 can pass through the handle through hole 1133 and the housing through holes 123 which overlap with each other, such that the handle 113 can be pivotally connected to the housing assembly 120 through this positioning pin 184, and the handle 113 can rotate relative to the housing assembly 120 with this positioning pin 184 as a rotation axis. Another one of the positioning pins 184 can pass through the button through hole 1113 and the housing through hole 123 which overlap with each other, such that the button 111 can be pivotally connected to the housing assembly 120 through this positioning pin 184, and the button 111 can rotate relative to the housing assembly 120 with this positioning pin 184 as a rotation axis.

Rotating the button 111 relative to the housing assembly 120 with the positioning pin 184 as a rotation axis can release the button 111 from the handle 113; at this time, the torsion provided by the first elastic element 180 pushes the handle movable end 1131E of the handle 113 away from the housing assembly 120. Then, the user can apply force on the handle movable end 1131E of the handle 113 to further rotate the handle 113 relative to the housing assembly 120 with the positioning pin 184 as a rotation axis, which causes the handle hook part 1134 of the handle 113 to move to disengage the support device 100 from the corresponding attachment structure of the cage; therefore, the support device 100 can be removed from the cage. The torsion provided by the first elastic element 180 can push the handle movable end 1131E of the handle 113 away from the housing assembly 120 even if the user does not exert force on the handle 113, which is conducive to the user holding or pushing the handle 113 for subsequent operations. For example, the button 111 can rotate along the first direction D1 (as shown in FIG. 6) with the positioning pin 184 as a rotation axis to release the handle 113; the handle 113 can rotate along the second direction D2 (as shown in FIG. 6) with the positioning pin 184 as a rotation axis at this time to disengage the support device 100 from the corresponding attachment structure of the cage. The first direction D1 can be different from the second direction D2. In an embodiment, the first direction D1 can be clockwise, and the second direction D2 can be counterclockwise.

At least a portion of the second elastic element 182 is disposed in the recess 124 of the housing assembly 120. For example, the second elastic element 182 is a compression spring or a tension spring. The force provided by the second elastic element 182 can cause the button 111 to rotate in the direction opposite to the first direction D1 (as shown in FIG. 6) and return to the position shown in FIGS. 1, 2 and 6. The second elastic element 182 can return to the position shown in FIGS. 1, 2 and 6 without force exerted by the user. The first elastic element 180 may be made of a metal material, such as SUS304 stainless steel. The second elastic element 182 may be made of a metal material, such as steel.

The connection element 186 includes first pillar portions 1862, second pillar portions 1863 and a connection portion 1861 disposed between the first pillar portions 1862 and the second pillar portions 1863. The first pillar portion 1862 and the second pillar portion 1863 extend toward different directions. The first pillar portions 1862 extend from a first surface of the connection portion 1861 toward the panel assembly 110. The first pillar portions 1862 can be separated from each other. The second pillar portions 1863 extend from a second surface of the connection portion 1861 toward the bracket assembly 140. The second pillar portions 1863 can be separated from each other. The first surface of the connection portion 1861 is opposite to the second surface of the connection portion 1861. In the present embodiment, the length of the first pillar portion 1862 can be larger than a length of the second pillar portion 1863, but the present disclosure is not limited thereto. As shown in FIGS. 1, 2 and 6, a portion of the connection element 186 passes through the housing assembly 120 and is disposed in the hole 1135 of the panel assembly 110, and another portion of the connection element 186 passes through the electromagnetic shielding assembly 130 and the bracket assembly 140. Specifically, the connection portion 1861 of the connection element 186 can be disposed in the housing assembly 120, two first pillar portions 1862 pass through the housing body 121 from opposite sides of the housing bulge part 122 and are disposed in the hole 1135 of the panel assembly 110, the second pillar portions 1863 pass through the first through holes 133 of the electromagnetic shielding assembly 130 and the first bracket through holes 143 of the bracket assembly 140 and be exposed by the penetrating holes 167 of the accommodation assembly 160. The connection portion 1861 of the connection element 186 can contact or abut the front surface of the body 131 of the electromagnetic shielding assembly 130. The first column 142 of the bracket assembly 140 can pass through the positioning hole 132 of the electromagnetic shielding assembly 130 and contact the connection portion 1861 of the connection element 186. The connection element 186 may be made of a polymer material, such as polycarbonate.

The fastening hole 154 of the bracket assembly 140 can overlap the connection hole 166 of the accommodation assembly 160, and the fastener 188 can pass through the fastening hole 154 and the connection hole 166 which overlap with each other; therefore, the bracket assembly 140 can be fastened to the accommodation assembly 160 through the fastener 188. For example, the fastener 188 is a pin. The fastener 188 may be made of a conductive material, such as SUS416 stainless steel. The positioning pin 184 may be made of a conductive material, such as carbon steel.

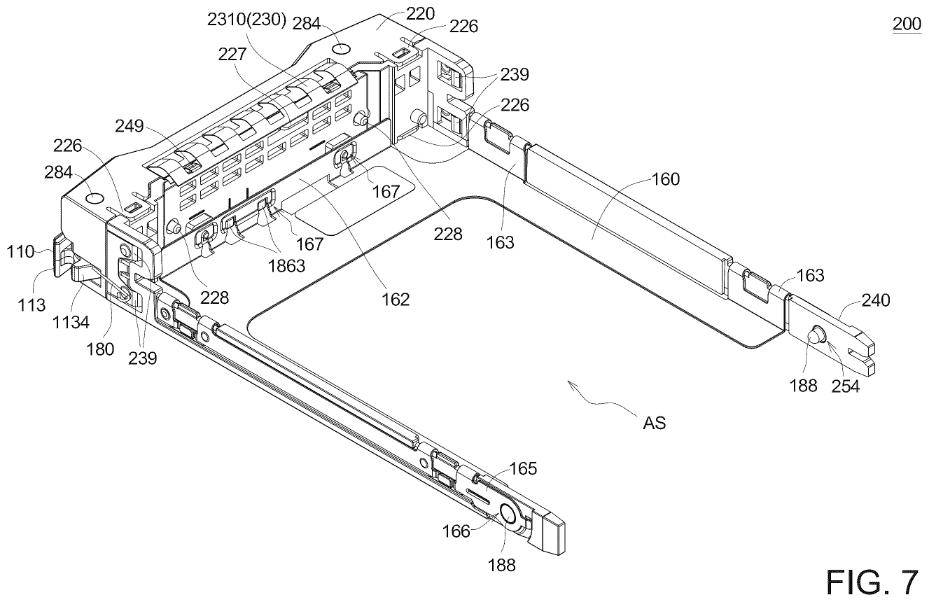

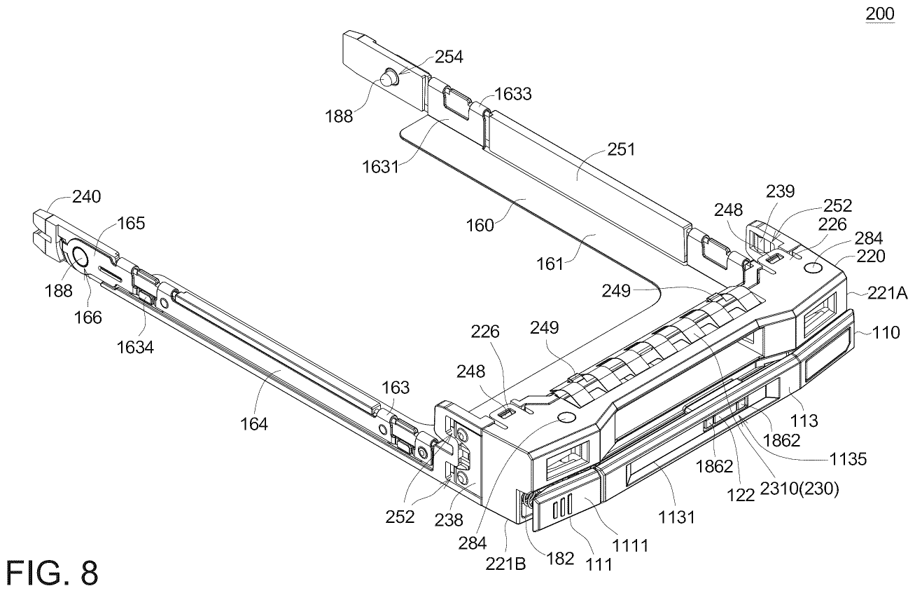

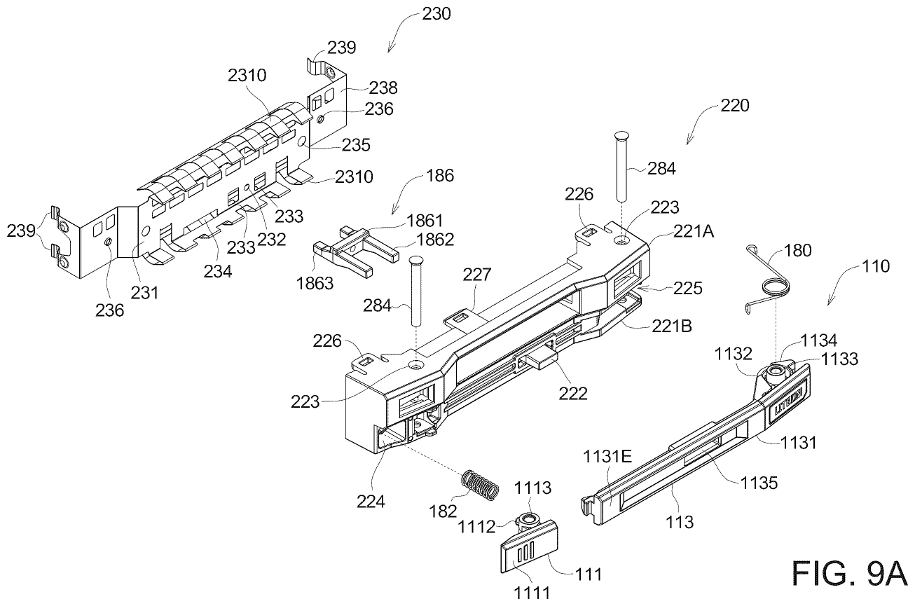

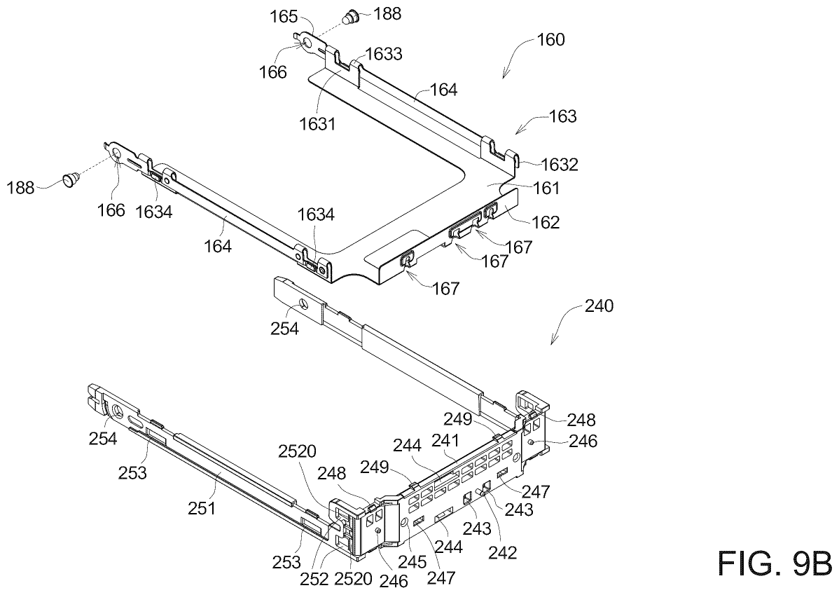

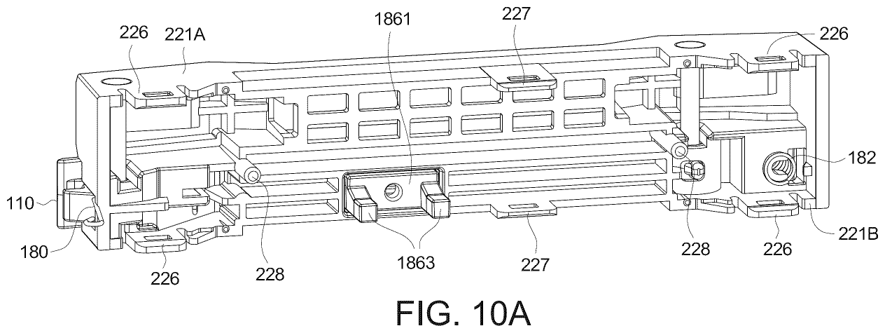

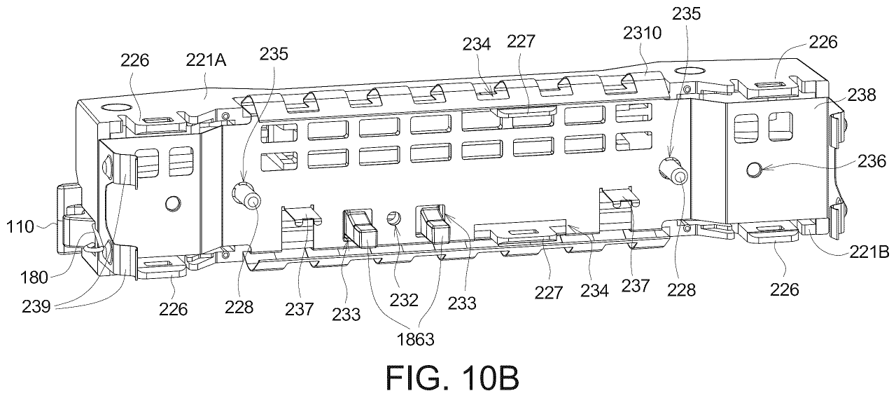

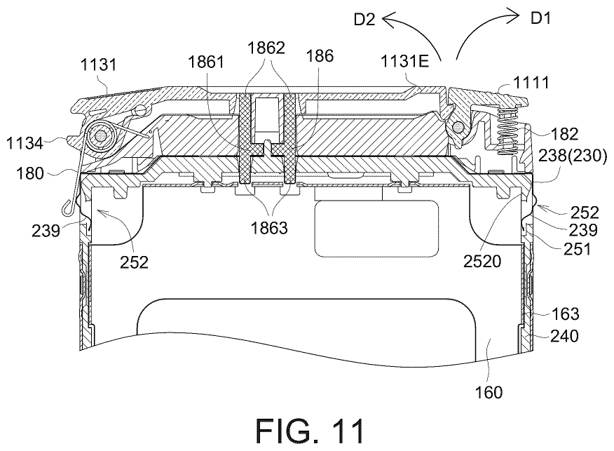

Referring to FIG. 7 to FIG. 11, FIG. 7 illustrates a schematic view of a support device 200 according to the second embodiment of the present disclosure, FIG. 8 illustrates a schematic view of the support device 200 according to the second embodiment of the present disclosure from different viewing angles, FIG. 9A illustrates a schematic exploded view of some elements of the support device 200 according to the second embodiment of the present disclosure, FIG. 9B illustrates a schematic exploded view of some elements of the support device 200 according to the second embodiment of the present disclosure, FIG. 10A illustrates a schematic view of the assembly of some elements of the support device 200 according to the second embodiment of the present disclosure, FIG. 10B illustrates a schematic view of the assembly of some elements of the support device 200 according to the second embodiment of the present disclosure, and FIG. 11 illustrates a partial perspective view of the support device 200 according to the second embodiment of the present disclosure, viewed from top of the support device 200.

The differences between the support device 200 and the support device 100 shown in FIG. 1 to FIG. 6 are that the housing assembly 220, the electromagnetic shielding assembly 230 and the bracket assembly 240 can have different structures, and the positioning pin 284 of the support device 200 and the positioning pin 184 of the support device 100 can have different sizes. In addition, some elements in the second embodiment shown in FIG. 7 to FIG. 11 are the same or similar to some elements in the first embodiment shown in FIG. 1 to FIG. 6; these elements are indicated by the same reference numerals; the descriptions of these elements are shown in the previous paragraphs and will not be repeated here.

The support device 200 includes a panel assembly 110, an electromagnetic shielding assembly 230, a housing assembly 220, a bracket assembly 240 and an accommodation assembly 160. The housing assembly 220 is disposed between the panel assembly 110 and the electromagnetic shielding assembly 230. The electromagnetic shielding assembly 230 is disposed between the housing assembly 220 and the bracket assembly 240. The accommodation assembly 160 is disposed on the bracket assembly 240 and is used to accommodate or mount electronic equipment. As shown in FIG. 9A, the panel assembly 110 includes a hole 1135. As shown in FIG. 9A, the housing assembly 220 includes a housing bulge part 222. As shown in FIG. 8, the housing bulge part 222 of the housing assembly 220 is disposed in the hole 1135 of the panel assembly 110, and the housing bulge part 222 is exposed by the hole 1135 of the panel assembly 110.

The height of the housing assembly 220 in the longitudinal direction can be larger than the height of the housing assembly 120 in the longitudinal direction. The housing assembly 220 includes an upper housing body 221A, a lower housing body 221B, a housing bulge part 222, a housing through hole 223, a recess 224, a channel 225, a housing snap portion 226, an extended piece 227 and a housing limit portion 228. In the present embodiment, the drawings show that the housing assembly 220 includes two housing through holes 223, four housing snap portions 226, two extended pieces 227 and two housing limit portions 228; however, the numbers of the housing through hole 223, the housing snap portion 226, the extended piece 227 and the housing limit portion 228 are not limited to the numbers shown in the drawings. The lower housing body 221B is disposed under the upper housing body 221A. The lower housing body 221B can be connected to the upper housing body 221A. The upper housing body 221A may further include vent holes (as shown in FIG. 7) which can improve the heat dissipation of the support device 200. The housing bulge part 222 protrudes from a front surface of the lower housing body 221B and extends toward the panel assembly 110. The front surface of the lower housing body 221B faces the rear surface of the panel assembly 110. The position of the housing bulge part 222 can correspond to the position of the hole 1135 of the panel assembly 110. The housing through hole 223 may be disposed at opposite ends of the upper housing body 221A. The housing through hole 223 may extend along the longitudinal direction and penetrate the upper housing body 221A and the lower housing body 221B. The recess 224 and the channel 225 can be disposed at opposite ends of the lower housing body 221B. The recess 224 has an opening toward the button 111 of the panel assembly 110. The channel 225 has an opening toward the handle 113 of the panel assembly 110 and the outside of the support device 200. The channel 225 is used to accommodate at least a portion of the handle bulge part 1132 and at least a portion of the handle hook part 1134 (as shown in FIG. 7 and FIG. 11). The channel 225 can communicate with one of the housing through holes 223.

As shown in FIG. 10A, two housing snap portions 226 protrude from a rear surface of the upper housing body 221A and extends toward the electromagnetic shielding assembly 230, and two housing snap portions 226 protrude from a rear surface of the lower housing body 221B and extends toward the electromagnetic shielding assembly 230. The rear surface of the upper housing body 221A faces the electromagnetic shielding assembly 230. The rear surface of the lower housing body 221B is opposite to the front surface of the lower housing body 221B. The rear surface of the lower housing body 221B faces the electromagnetic shielding assembly 230. The housing snap portions 226 can be disposed on the upper housing body 221A and the lower housing body 221B and separated from each other. In the present embodiment, two housing snap portions 226 are disposed close to an upper surface of the upper housing body 221A, and two housing snap portions 226 are disposed close to a lower surface of the lower housing body 221B; the present disclosure is not limited thereto. The extended piece 227 protrudes from the rear surface of the upper housing body 221A and the rear surface of the lower housing body 221B and extends toward the electromagnetic shielding assembly 230. The extended pieces 227 can be disposed on the upper housing body 221A and the lower housing body 221B and separated from each other. In the present embodiment, one extended piece 227 is disposed close to the upper surface of the upper housing body 221A, and another extended piece 227 is disposed close to the lower surface of the lower housing body 2211B; the present disclosure is not limited thereto. The extended pieces 227 can be disposed between the housing snap portions 226. The housing limit portions 228 can be disposed at opposite ends of the lower housing body 221B. The housing limit portion 228 protrudes from the rear surface of the lower housing body 221B and extends toward the electromagnetic shielding assembly 230. The housing limit portions 228 can be separated from each other. As shown in FIG. 8, the panel assembly 110 can cover the front surface of the lower housing body 221B. The panel assembly 110 can be disposed under the upper housing body 221A. The housing assembly 220 may be made of a polymer material, such as polycarbonate (PC), acrylonitrile butadiene styrene (ABS) or a combination thereof.

The height of the electromagnetic shielding assembly 230 in the longitudinal direction can be larger than the height of the electromagnetic shielding assembly 130 in the longitudinal direction. The electromagnetic shielding assembly 230 includes a body 231, a finger portion 2310, a positioning hole 232, a first through hole 233, a second through hole 234, a third through hole 235, a fourth through hole 236, a conductive piece 237, an extended portion 238 and an elastic structure 239. In the present embodiment, the drawings show that the electromagnetic shielding assembly 230 includes two finger portions 2310, two first through holes 233, two second through holes 234, two third through holes 235, two fourth through holes 236, two conductive pieces 237, two extended portions 238 and four elastic structures 239; however, the numbers of the finger portion 2310, the first through hole 233, the second through hole 234, the third through hole 235, the fourth through hole 236, the conductive piece 237, the extended portion 238 and the elastic structure 239 are not limited to the numbers shown in the drawings. The body 231 is disposed or connected between two finger portions 2310. Two finger portions 2310 are disposed on opposite sides of the body 231. The finger portions 2310 can extend toward the housing assembly 220. The finger portions 2310 can be separated from each other. The body 231 can cover the rear surface of the upper housing body 221A of the housing assembly 220 and the rear surface of the lower housing body 221B of the housing assembly 220. One finger portion 2310 of the two finger portions 2310 can cover the upper surface of the upper housing body 221A of the housing assembly 220, and the other one of the two finger portions 2310 can cover the lower surface of the lower housing body 221B of the housing assembly 220. As shown in FIG. 10B, the positioning hole 232 can extend from a front surface of the body 231 to a rear surface of the body 231 opposite the front surface. The front surface of the body 231 faces the rear surface of the upper housing body 221A and the rear surface of the lower housing body 221B of the housing assembly 220. The rear surface of the body 231 faces the bracket assembly 240. As shown in FIG. 10B, two first through holes 233 can be disposed on opposite sides of the positioning hole 232. The first through holes 233 can extend from the front surface of the body 231 to the rear surface of the body 231. As shown in FIG. 10B, the second through hole 234 can extend from the front surface of the body 231 to the rear surface of the body 231. Two second through holes 234 may be disposed along the longitudinal direction. The position of the second through hole 234 can correspond to the position of the extended piece 227 of the housing assembly 220. As shown in FIG. 10B, two third through holes 235 can be disposed on opposite sides of the positioning hole 232. The third through holes 235 can extend from the front surface of the body 231 to the rear surface of the body 231. The position of the third through hole 235 can correspond to the position of the housing limit portion 228 of the housing assembly 220. The conductive piece 237 can protrude from the rear surface of the body 231 and extend toward the bracket assembly 240. The conductive pieces 237 can be separated from each other. Two conductive pieces 237 can be disposed on opposite sides of the positioning hole 232. The conductive pieces 237 can be disposed between the third through holes 235. The positioning hole 232, the first through holes 233 and the second through holes 234 can be disposed between two conductive pieces 237. The conductive piece 237 can be formed by bending the material of the body 231.

Two extended portions 238 can be disposed at opposite ends of the body 231. The extended portion 238 can extend from the end of the body 231 toward the outside of the support device 200. The extended portion 238 may have a bending structure. The extended portion 238 may be bent toward the bracket assembly 240. The elastic structure 239 is disposed at the end of the extended portion 238. The extended portion 238 can be connected between the elastic structure 239 and the body 231. In the present embodiment, each extended portion 238 can be connected to two elastic structures 239. The elastic structure 239 may have a curved structure. The elastic structure 239 may include a concave part that is recessed toward the interior of the support device 200 (i.e. the opening of the concave part is toward the outside of the support device 200). As shown in FIG. 10B, two fourth through holes 236 can be disposed on opposite sides of the positioning hole 232. The fourth through hole 236 can penetrate the extended portion 238. The third through hole 235 can be disposed between the fourth hole 236 and the conductive piece 237. The housing assembly 220 can cover the front surface of the body 231 of the electromagnetic shielding assembly 230. When the support device 200 is installed in the cage, the elastic structure 239 can be within a corresponding accommodation hole in the cage to improve the assembly stability of the support device 200 and the cage. The electromagnetic shielding assembly 230 may be made of a conductive material, such as SUS301 stainless steel. In an embodiment, the extended portion 238 and/or the elastic structure 239 can contact the cage for electrostatic discharge, which can improve the electrostatic protection capability of the support device 200.

The electromagnetic shielding assembly 230 may further include vent holes penetrating the body 231, and the position of the vent holes of the electromagnetic shielding assembly 230 can correspond to the position of the vent holes of the upper housing body 221A. For example, the vent holes of the electromagnetic shielding assembly 230 can be disposed above the positioning hole 232 and the first through holes 233.

The height of the bracket assembly 240 in the longitudinal direction can be larger than the height of the bracket assembly 140 in the longitudinal direction. The bracket assembly 240 includes a bracket body 241, a first column 242, a first bracket through hole 243, a second bracket through hole 244, a third bracket through hole 245, a second column 246, a fourth bracket through hole 247, a snap portion 248, an extension structure 249, a side arm 251, a receiving hole 252, a concavity 253 and a fastening hole 254. In the present embodiment, the drawings show that the bracket assembly 240 includes one first column 242, two first bracket through holes 243, two second bracket through holes 244, two third bracket through holes 245, two second columns 246, two fourth bracket through holes 247, four snap portions 248, four extension structures 249, two side arms 251, four receiving holes 252, four concavities 253 and two fastening holes 254; however, the numbers of the first column 242, the first bracket through hole 243, the second bracket through hole 244, the third bracket through hole 245, the second column 246, the fourth bracket through hole 247, the snap portion 248, the extension structure 249, the side arm 251, the receiving hole 252, the concavity 253 and the fastening hole 254 are not limited to the numbers shown in the drawings. The bracket body 241 is disposed or connected between two side arms 251. The side arm 251 can extend in a direction away from the electromagnetic shielding assembly 230.

As shown in FIG. 9B, the first column 242 is disposed on a front surface of the bracket body 241. The first column 242 protrudes from the front surface of the bracket body 241. The front surface of the bracket body 241 faces the rear surface of the body 231 of the electromagnetic shielding assembly 230. The position of the first column 242 can correspond to the position of the positioning hole 232 of the electromagnetic shielding assembly 230. Two first bracket through holes 243 can be disposed on opposite sides of the first column 242. The first bracket through hole 243 can extend from the front surface of the bracket body 241 to a rear surface of the bracket body 241 opposite the front surface of the bracket body 241. The position of the first bracket through holes 243 can correspond to the position of the first through holes 233 of the electromagnetic shielding assembly 230. Two second bracket through holes 244 can extend from the front surface of the bracket body 241 to the rear surface of the bracket body 241. Two second bracket through holes 244 can be disposed along the longitudinal direction. The position of the second bracket through holes 244 can correspond to the position of the second through holes 234 of the electromagnetic shielding assembly 230. Two third bracket through holes 245 can be disposed on opposite sides of the first column 242. The third bracket through holes 245 can extend from the front surface of the bracket body 241 to the rear surface of the bracket body 241. The position of the third bracket through holes 245 can correspond to the position of the third through holes 235 of the electromagnetic shielding assembly 230. The second columns 246 are disposed on the front surface of the bracket body 241. The second columns 246 protrude from the front surface of the bracket body 241. Two second columns 246 can be disposed on opposite sides of the bracket body 241. Two second columns 246 can be disposed on opposite sides of the first column 242. The position of the second columns 246 can correspond to the position of the fourth through holes 236 of the electromagnetic shielding assembly 230. Two fourth bracket through holes 247 can be disposed on opposite sides of the first column 242. The fourth bracket through holes 247 can extend from the front surface of the bracket body 241 to the rear surface of the bracket body 241. The position of the fourth bracket through holes 247 can correspond to the position of the conductive pieces 237 of the electromagnetic shielding assembly 230. The first column 242, the first bracket through holes 243 and the second bracket through holes 244 can be disposed between two fourth bracket through holes 247. The third bracket through hole 245 can be disposed between the second column 246 and the fourth bracket through hole 247. Two of four snap portions 248 are disposed separately on the first edge of the bracket body 241 and protrude from the first edge of the bracket body 241, and the other two of the four snap portions 248 are disposed separately on the second edge of the bracket body 241 and protrude from the second edge of the bracket body 241; the first edge is opposite to the second edge. The position of the snap portions 248 can correspond to the housing snap portions 226 of the housing assembly 220. Two of four extension structures 249 are disposed separately on the first edge of the bracket body 241 and protrude from the first edge of the bracket body 241, and the other two of the four extension structures 249 are disposed separately on the second edge of the bracket body 241 and protrude from the second edge of the bracket body 241. The extension structure 249 can be disposed between the snap portions 248.

The housing snap portion 226 of the housing assembly 220 is coupled to the snap portion 248 of the bracket assembly 240 so that the housing assembly 220 is fixed to the bracket assembly 240. The extended piece 227 of the housing assembly 220 passes through the second through hole 234 of the electromagnetic shielding assembly 230 and the second bracket through hole 244 of the bracket assembly 240. The housing limit portion 228 of the housing assembly 220 passes through the third through hole 235 of the electromagnetic shielding assembly 230 and the third bracket through hole 245 of the bracket assembly 240. The first column 242 of the bracket assembly 240 can pass through the positioning hole 232 of the electromagnetic shielding assembly 230. The second column 246 of the bracket assembly 240 can pass through the fourth through hole 236 of the electromagnetic shielding assembly 230. The conductive piece 237 of the electromagnetic shielding assembly 230 can pass through the fourth bracket through hole 247 of the bracket assembly 240. The extension structure 249 of the bracket assembly 240 can pass through the finger portion 2310 of the electromagnetic shielding assembly 230. The extension structures 249 of the bracket assembly 240 can be disposed in the gaps between the fingers of the finger portions 2310 of the electromagnetic shielding assembly 230. The extension structures 249 can cover a portion of the surface of the finger portion 2310. The movement of the finger portions 2310 can be limited by the extension structures 249.

The receiving holes 252, the concavities 253 and the fastening holes 254 are disposed on a side of the bracket assembly 240. The receiving holes 252, the concavities 253 and the fastening holes 254 are disposed on the side arms 251. The receiving holes 252 and the fastening holes 254 can penetrate the side arms 251. The opening of the concavity 253 faces the outside of the support device 200. The concavity 253 may be recessed from the outside toward the inside of the support device 200. The concavity 253 may be disposed between the receiving hole 252 and the fastening hole 254. In the present embodiment, two receiving holes 252 can be disposed along the longitudinal direction on one side arm 251. The elastic structure 239 of the electromagnetic shielding assembly 230 can be disposed in the receiving hole 252 so that the electromagnetic shielding assembly 230 is coupled to the bracket assembly 240. As shown in FIG. 11, the receiving hole 252 can include a guide ramp 2520 for guiding the elastic structure 239 into the receiving hole 252. As shown in FIG. 11, when the electromagnetic shielding assembly 230 is coupled to the bracket assembly 240, the end of the elastic structure 239 is limited by the side arm 251 to fix the electromagnetic shielding assembly 230 to the bracket assembly 240. The assembly of the electromagnetic shielding assembly 230 and the bracket assembly 240 can be achieved through the guiding of the guide ramp 2520, which is conducive to automated assembly. The electromagnetic shielding assembly 230 can cover the front surface of the bracket body 241 of the bracket assembly 240. The bracket assembly 240 may be made of a polymer material, such as polycarbonate (PC), acrylonitrile butadiene styrene (ABS) or a combination thereof.

The bracket assembly 240 may further include vent holes penetrating the bracket body 241, and the position of the vent holes of the bracket assembly 240 can correspond to the position of the vent holes of the electromagnetic shielding assembly 230 and the vent holes of the upper housing body 221A. For example, the vent holes of the bracket assembly 240 can be disposed above the first column 242, the first bracket through holes 243 and the fourth bracket through holes 247.

The front plate 162 of the accommodation assembly 160 can cover the rear surface of the bracket body 241. The connection piece 1633 of the coupling structure 163 protrudes from a surface of the back plate 1631 that is toward the outside of the support device 200. The back plate 1631, the cover piece 1632, the connection piece 1633 and the limit element 1634 of the coupling structure 163 can define a holding space, and the side arm 251 of the bracket assembly 240 is disposed in the holding space. Specifically, when the accommodation assembly 160 is assembled to the bracket assembly 240, the back plate 1631 covers the inner surface of the side arm 251 of the bracket assembly 240, the cover piece 1632 covers the outer surface of the side arm 251 of the bracket assembly 240 and the limit element 1634 is disposed in the cavity 253 of the bracket assembly 240; the inner surface of the side arm 251 of the bracket assembly 240 is opposite to the outer surface of the side arm 251 of the bracket assembly 240; the outer surface of the side arm 251 of the bracket assembly 240 faces the outside of the support device 200. The back plate 1631, the cover piece 1632 and the connection piece 1633 cover the side arm 251 of the bracket assembly 240, and the limit element 1634 is disposed in the cavity 253 of the bracket assembly 240, so that the movement of the bracket assembly 240 relative to the accommodation assembly 160 can be limited and the bracket assembly 240 can be fixed to the accommodation assembly 160. The connection arm 164 of the coupling structure 163 can cover the outer surface of the side arm 251 of the bracket assembly 240. The connection arm 164 improves the structural strength of the accommodation assembly 160 and the assembly stability of the bracket assembly 240 and the accommodation assembly 160. The position of the connection holes 166 can correspond to the fastening holes 254 of the bracket assembly 240.

The electronic equipment can be disposed in the accommodation space AS of the accommodation assembly 160 and coupled to the bracket assembly 240 and/or the accommodation assembly 160. The electronic equipment can contact the bracket assembly 240 and/or the accommodation assembly 160. In an embodiment, the electronic equipment can be fixed (or coupled) in the accommodation space AS of the accommodation assembly 160 without using fastening components such as screws. The conductive piece 237 of the electromagnetic shielding assembly 230 can contact the front plate 162 of the accommodation assembly 160. The electromagnetic shielding assembly 230, the accommodation assembly 160 and the electronic equipment mounted on the support device 200 can form a conductive path for electrostatic discharge, grounding, etc., which can effectively increase the electromagnetic interference protection.

The support device 200 may further include a first elastic element 180, a second elastic element 182, positioning pins 284, a connection element 186 and fasteners 188. The length of the positioning pin 284 can be larger than the length of the positioning pin 184. A portion of the first elastic element 180 may be in the channel 225 of the housing assembly 220, and another portion of the first elastic element 180 may protrude from the a side surface of the housing assembly 220 (as shown in FIG. 7). At least a portion of the handle bulge part 1132 is disposed in the channel 225 of the housing assembly 220 so that the handle through hole 1133 overlaps one of the housing through holes 223 of the housing assembly 220. At least a portion of the button bulge part 1112 is disposed in the housing assembly 220 so that the button through hole 1113 overlaps another one of the housing through holes 223 of the housing assembly 220. One of the positioning pins 284 can pass through the handle through hole 1133 and the housing through holes 223 which overlap with each other, such that the handle 113 can be pivotally connected to the housing assembly 220 through this positioning pin 284, and the handle 113 can rotate relative to the housing assembly 220 with this positioning pin 284 as a rotation axis. Another one of the positioning pins 284 can pass through the button through hole 1113 and the housing through hole 223 which overlap with each other, such that the button 111 can be pivotally connected to the housing assembly 220 through this positioning pin 284, and the button 111 can rotate relative to the housing assembly 220 with this positioning pin 284 as a rotation axis.

Rotating the button 111 relative to the housing assembly 220 with the positioning pin 284 as a rotation axis can release the button 111 from the handle 113; at this time, the torsion provided by the first elastic element 180 pushes the handle movable end 1131E of the handle 113 away from the housing assembly 220. Then, the user can apply force on the handle movable end 1131E of the handle 113 to further rotate the handle 113 relative to the housing assembly 220 with the positioning pin 284 as a rotation axis, which causes the handle hook part 1134 of the handle 113 to move to disengage the support device 200 from the corresponding attachment structure of the cage; therefore, the support device 200 can be removed from the cage. The torsion provided by the first elastic element 180 can push the handle movable end 1131E of the handle 113 away from the housing assembly 220 even if the user does not exert force on the handle 113, which is conducive to the user holding or pushing the handle 113 for subsequent operations. For example, the button 111 can rotate along the first direction D1 (as shown in FIG. 11) with the positioning pin 284 as a rotation axis to release the handle 113; the handle 113 can rotate along the second direction D2 (as shown in FIG. 11) with the positioning pin 284 as a rotation axis at this time to disengage the support device 200 from the corresponding attachment structure of the cage. The first direction D1 can be different from the second direction D2. In an embodiment, the first direction D1 can be clockwise, and the second direction D2 can be counterclockwise.

At least a portion of the second elastic element 182 is disposed in the recess 224 of the housing assembly 220. The force provided by the second elastic element 182 can cause the button 111 to rotate in the direction opposite to the first direction D1 (as shown in FIG. 11) and return to the position shown in FIGS. 7, 8 and 11.

The first pillar portions 1862 of the connection element 186 extend from a first surface of the connection portion 1861 toward the panel assembly 110. The second pillar portions 1863 of the connection element 186 extend from a second surface of the connection portion 1861 toward the bracket assembly 240. The first surface of the connection portion 1861 is opposite to the second surface of the connection portion 1861. In the present embodiment, the length of the first pillar portion 1862 can be larger than a length of the second pillar portion 1863, but the present disclosure is not limited thereto. As shown in FIGS. 7, 8 and 11, a portion of the connection element 186 passes through the housing assembly 220 and is disposed in the hole 1135 of the panel assembly 110, and another portion of the connection element 186 passes through the electromagnetic shielding assembly 230 and the bracket assembly 240. Specifically, the connection portion 1861 of the connection element 186 can be disposed in the housing assembly 220, two first pillar portions 1862 pass through the lower housing body 221B from opposite sides of the housing bulge part 222 and are disposed in the hole 1135 of the panel assembly 110, the second pillar portions 1863 pass through the first through holes 233 of the electromagnetic shielding assembly 230 and the first bracket through holes 243 of the bracket assembly 240 and are exposed by the penetrating holes 167 of the accommodation assembly 160. The connection portion 1861 of the connection element 186 can contact or abut the front surface of the body 131 of the electromagnetic shielding assembly 230. The first column 242 of the bracket assembly 240 can pass through the positioning hole 232 of the electromagnetic shielding assembly 230 and contact the connection portion 1861 of the connection element 186.

The fastening hole 254 of the bracket assembly 240 can overlap the connection hole 166 of the accommodation assembly 160, and the fastener 188 can pass through the fastening hole 254 and the connection hole 166 which overlap with each other; therefore, the bracket assembly 240 can be fastened to the accommodation assembly 160 through the fastener 188.

The size of the support device of the present disclosure can be set according to the common cage/rack design guidelines in the industry, and the size of the support device of the present disclosure can be adjusted according to the size of the electronic equipment to be mounted. The support devices of the present disclosure can be adapted for electronic equipment with different form factors. For example, the support device 100 can be adapted for E3.S 1T solid-state drives based on EDSFF, and the support device 200 can be adapted for E3.S 2T solid-state drives based on EDSFF; the present disclosure is not limited thereto.

As compared with the conventional support device, the support devices of the present disclosure include a low number of elements and do not use elements with complex structures that are difficult to assemble automatically. Therefore, the manufacturing cost of the support devices of the present disclosure can be decreased, and the support devices of the present disclosure are suitable for automated assembly.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A support device for mounting electronic equipment, comprising:
a panel assembly comprising a hole;
an electromagnetic shielding assembly;
a housing assembly disposed between the panel assembly and the electromagnetic shielding assembly and comprising a housing bulge part, wherein the housing bulge part is disposed in the hole of the panel assembly, and the housing bulge part is exposed by the hole of the panel assembly;
a bracket assembly, wherein the electromagnetic shielding assembly is disposed between the housing assembly and the bracket assembly; and
an accommodation assembly on the bracket assembly for accommodating the electronic equipment.

2. The support device according to claim 1, further comprising a connection element, wherein a portion of the connection element passes through the housing assembly and is disposed in the hole of the panel assembly, and another portion of the connection element passes through the electromagnetic shielding assembly and the bracket assembly.

3. The support device according to claim 1, further comprising a connection element, wherein the connection element comprises a first pillar portion, a second pillar portion and a connection portion disposed between the first pillar portion and the second pillar portion, wherein the first pillar portion is disposed in the hole of the panel assembly, the connection portion is disposed in the housing assembly, and the second pillar portion passes through the electromagnetic shielding assembly and the bracket assembly.

4. The support device according to claim 3, wherein the connection element comprises two first pillar portions, and the first pillar portions are disposed on opposite sides of the housing bulge part.

5. The support device according to claim 1, wherein the electromagnetic shielding assembly comprises two finger portions and a body, the finger portions are disposed on opposite sides of the body, one of the finger portions covers a first surface of the housing assembly, and the other finger portion covers a second surface of the housing assembly.

6. The support device according to claim 5, wherein the electromagnetic shielding assembly comprises an extended portion and an elastic structure, wherein the extended portion is connected between the elastic structure and the body, the extended portion has a bending structure, the bracket assembly comprises a receiving hole on a side, and the elastic structure of the electromagnetic shielding assembly is disposed in the receiving hole of the bracket assembly so that the electromagnetic shielding assembly is coupled to the bracket assembly.

7. The support device according to claim 1, wherein the electromagnetic shielding assembly comprises an elastic structure, and the bracket assembly comprises a receiving hole on a side, the elastic structure of the electromagnetic shielding assembly is disposed in the receiving hole of the bracket assembly so that the electromagnetic shielding assembly is coupled to the bracket assembly.

8. The support device according to claim 1, wherein the accommodation assembly comprises a coupling structure, the coupling structure comprises a back plate, a cover piece, and a connection piece connected between the back plate and the cover piece, the bracket assembly is disposed in a holding space defined by the back plate, the cover piece and the connection piece.

9. The support device according to claim 8, wherein the connection piece protrudes from a surface of the back plate, the back plate covers an inner surface of the bracket assembly, the cover piece covers an outer surface of the bracket assembly, and the inner surface of the bracket assembly is opposite to the outer surface of the bracket assembly.

10. The support device according to claim 8, wherein the coupling structure comprises a limit element, the bracket assembly comprises a concavity, and the limit element of the coupling structure is disposed in the cavity of the bracket assembly.

11. The support device according to claim 10, wherein the coupling structure comprises two cover pieces, and the limit element is disposed between the cover pieces.

12. The support device according to claim 8, wherein the accommodation assembly comprises a bottom plate and a plurality of coupling structures disposed on opposite edges of the bottom plate.

13. The support device according to claim 1, wherein the electromagnetic shielding assembly comprises two finger portions and a body, the finger portions are disposed on opposite sides of the body, the bracket assembly comprises extension structures passing through the finger portions.

14. The support device according to claim 1, wherein the housing assembly comprises an extended piece passing through the electromagnetic shielding assembly and the bracket assembly.

15. The support device according to claim 14, wherein the housing assembly comprises a housing snap portion, the bracket assembly comprises a snap portion, and the housing snap portion is coupled to the snap portion.

16. The support device according to claim 15, further comprising a connection element, wherein the connection element comprises a first pillar portion, a second pillar portion and a connection portion disposed between the first pillar portion and the second pillar portion, the first pillar portion is disposed in the hole of the panel assembly, the connection portion is disposed in the housing assembly, and the second pillar portion passes through the electromagnetic shielding assembly and the bracket assembly.

17. The support device according to claim 1, further comprising an elastic element, wherein a portion of the elastic element is disposed in the housing assembly, and another portion of the elastic element is disposed in an accommodation space of the accommodation assembly for accommodating the electronic equipment.

18. The support device according to claim 17, wherein the elastic element is a torsion spring.

19. The support device according to claim 1, further comprising an elastic element, wherein a portion of the elastic element is disposed in the housing assembly, and another portion of the elastic element protrudes from a side surface of the housing assembly.

20. The support device according to claim 19, wherein the panel assembly comprises a handle, the handle comprises a handle body, a handle bulge part and a handle through hole, the handle bulge part protrudes from a surface of the handle body, the handle through hole penetrates the handle bulge part, and the hole is disposed in the handle body, and the elastic element is disposed on a side of the handle bulge part.

21. The support device according to claim 20, wherein the handle comprises a handle hook part disposed on the handle bulge part and extending toward the outside of the support device.

22. The support device according to claim 21, wherein the housing assembly comprises a housing body, a first housing through hole, a recess and a channel, the first housing through hole penetrates the housing body, the recess and the channel are disposed at opposite ends of the housing body, and the recess has an opening toward the panel assembly, the channel accommodates at least a portion of the handle bulge part and at least a portion of the handle hook part, and the channel communicates with the first housing through hole.

23. The support device according to claim 22, wherein the channel has an opening toward the panel assembly and the outside of the support device.

24. The support device according to claim 22, wherein the handle comprises a handle movable end, the panel assembly comprises a button, and the button abuts the handle movable end of the handle, the button comprises a button body, a button bulge part and a button through hole, the button bulge part protrudes from a surface of the button body, and the button through hole penetrates the button bulge part.

25. The support device according to claim 24, further comprising a first positioning pin and a second positioning pin, wherein the housing assembly comprises a second housing through hole penetrating the housing body, the first positioning pin passes through the first housing through hole and the handle through hole so that the handle is pivotally connected to the housing assembly, and the second positioning pin passes through the second housing through hole and the button through hole so that the button is pivotally connected to the housing assembly.

26. The support device according to claim 1, wherein the housing assembly comprises a housing body and housing snap portions, a portion of the housing snap portions is disposed close to a first surface of the housing body, another portion of the housing snap portions is disposed close to a second surface of the housing body, and the housing snap portions are coupled to the bracket assembly.

27. The support device according to claim 26, wherein the housing assembly comprises a first extended piece and a second extended piece, the first extended piece is disposed close to the first surface of the housing body, the second extended piece is disposed close to the second surface of the housing body, and the first extended piece and the second extended piece extend toward the electromagnetic shielding assembly and pass through the bracket assembly.

28. The support device according to claim 27, wherein the electromagnetic shielding assembly comprises two through holes, and the first extended piece and the second extended piece pass through the through holes respectively.

29. The support device according to claim 27, wherein the housing assembly comprises housing limit portions, the housing limit portions protrude from a surface of the housing body and extend toward the electromagnetic shielding assembly, the housing limit portions pass through the bracket assembly, and the first extended piece and the second extended piece are disposed between the housing limit portions.

30. The support device according to claim 29, wherein the electromagnetic shielding assembly comprises through holes, and the housing limit portions pass through the through holes respectively.

31. The support device according to claim 30, wherein the electromagnetic shielding assembly comprises a conductive piece disposed between the through holes.

32. The support device according to claim 1, wherein the electromagnetic shielding assembly comprises a body, an extended portion, an elastic structure and a through hole, the extended portion is connected between the elastic structure and the body, the extended portion is bent toward the bracket assembly, and the through hole penetrates the extended portion.

33. The support device according to claim 32, wherein the bracket assembly comprises a column passing through the through hole of the electromagnetic shielding assembly.

34. The support device according to claim 1, wherein the bracket assembly comprises a column and two bracket through holes disposed on opposite sides of the column, and the column passes through the electromagnetic shielding assembly.
